(19) United States
(12) Patent Application Publication
(10) Pub. No.: US 2009/0129031 A1
(43) Pub. Date: May 21, 2009

(54) Planar Element Module, Manufacturing Method of Planar Element Module, and Planar Element Device

(75) Inventors: Takao Someya, Tokyo (JP); Takayasu Sakurai, Tokyo (JP); Hiroshi Kawaguchi, Kobe-shi (JP); Tsuyoshi Sekitani, Tokyo (JP)

Correspondence Address: OLIFF & BERRIDGE, PLC, P.O. BOX 320850, ALEXANDRIA, VA, 22320-4850, US

(73) Assignee: THE UNIVERSITY OF TOKYO, Tokyo (JP)

(21) Appl. No.: 11/663,773

(22) PCT Filed: Sep. 27, 2005
(86) PCT No.: PCT/JP05/17777

§ 371 Date: Jul. 30, 2008

(30) Foreign Application Priority Data
Sep. 27, 2004 (JP) 2004-280197

(51) Int. Cl. H05K 7/00; H05K 3/00

(52) U.S. Cl. 361/729; 361/728; 29/829

(57) ABSTRACT

A flat pressure sensor of the invention is prepared by processing a thin film of a polymer material to have plurality of substantially square openings 24. A planar member 22 of the flat pressure sensor thus obtained has a net-like structure including multiple element formation areas 26 and multiple bridging areas 28 that respectively bridge the multiple element formation areas 26. Pressure sensor elements 30 are provided in the multiple element formation areas 26 of the planar member 22. A wiring to the pressure sensor elements 30 is formed on the multiple bridging areas 28. The net-like structure enables the flat pressure sensor to be stretched in diagonal directions without arrangement of the bridging areas 28 and to be deformed to a curved surface. The flat pressure sensor of the invention is thus attached to a curved surface, for example, a spherical surface.

### TECHNICAL FIELD

The present invention relates to a planar element module, a manufacturing method of the planar element module, and a planar element device. More specifically the invention pertains to a planar element module with multiple elements placed on an identical plane, a manufacturing method of such a planar element module, and a planar element device including such a planar element module.

### BACKGROUND ART

There have been researches and developments regarding deformable planar element modules. The planar element module includes multiple elements, for example, multiple sensor elements for measuring or detecting a physical quantity like temperature, pressure, or light, which are formed in a flexible film, for example, a polymer film (see, for example, Non-Patent Document 1 and Non-Patent Document 2). The planar element module is used, for example, as a flexible sensor attached to movable parts of robotics or machinery.

Non-Patent Document 1; T. Someya, T. Sekitani, S. Iba, Y. Kato, H. Kawaguchi, and T. Sakurai, ‘A large-area, flexible pressure sensor matrix with organic field-effect transistors for artificial skin applications’, Proceedings of the National Academy of Sciences of the United States of America, 101, 9966 (2004)
Non-Patent Document 2: T. Someya, H. Kawaguchi, and T. Sakurai, ‘Cut-and-paste organic FET customized ICs for application of artificial skin’ 2004 IEEE International Solid-State Circuits Conference (ISSCC), 16. 2, pp. 288-289, San Francisco, Calif., (Feb. 14-19, 2004)

### DISCLOSURE OF THE INVENTION

The prior art planar element module is flexibly bent and curved but has only low tensibility for deformation in a planar direction. The proposed planar element module may be wrapped round a straight line-defining surface, for example, a cylindrical surface or a cone surface. It is, however, extremely difficult to attach this prior art planar element module to a curved-line defining surface, for example, a spherical surface or a paraboloidal surface.

There is a requirement for providing a planar element module and a planar element device that are tensile in a planar direction. There is also a requirement for providing a planar element module and a planar element device that are deformable to a curved surface. The manufacturing method of the planar element module is required to manufacture a planar element module that is tensile in the planar direction or a planar element module that is deformable to a curved surface.

In order to satisfy at least part of the above and the other related requirements, the planar element module, the manufacturing method of the planar element module, and the planar element device of the invention have the configurations discussed below.

The present invention is directed to a planar element module. The planar element module includes: a planar member having multiple element location areas that are arranged in a substantially identical plane and multiple bridging areas that respectively bridge the multiple element location areas and are bending deformable; multiple elements formed in at least part of the multiple element location areas of the planar member; and a wiring that is made of an electrically conductive material and is formed on at least part of the multiple bridging areas to supply electricity to the multiple elements.

In the planar element module of the invention, the in-plane bending deformation of the multiple bridging areas enables the planar member to be stretched in a planar direction, while not deforming the multiple element location areas. The planar element module of the invention is thus tensile in the planar direction. The in-plane and the out-of-plane bending deformability of the multiple bridging areas of the planar member enable deformation of the planar member to a curved surface while not deforming the multiple element location areas. The planar element module of the invention is thus deformable to a curved surface and is readily attached to the curved surface. The terminology ‘substantially identical plane’ includes not only an identical plane or an identical curved surface but a slightly undulated portion of the identical plane or the identical curved surface.

In one aspect of the planar element module of the invention, the planar member has the multiple bridging areas that are bent and deformed to be stretched in a predetermined direction by application of a tension in the predetermined direction. The planar element module of this aspect is accordingly tensile in the predetermined direction. In this structure, the planar member may have the multiple bridging areas that are arranged in a different direction from the predetermined direction.

In another aspect of the planar element module of the invention, the planar member having the multiple element location areas and the multiple bridging areas is provided by formation of plural openings on a thin film of a polymer material. In this application, the thin film may be either a polyethylene naphthalate film having a thickness of not greater than 1 mm or a polyimide film having a thickness of not greater than 1 mm. The thickness of the thin film is not restricted to be not greater than 1 mm but may be varied adequately according to the processing accuracy and the other requirements. For example, the thin film may have a thickness of not less than 1 mm or a thickness of, for example, 500 μm, 300 μm, 100 μm, or 50 μm. The material of the thin film is not restricted to polyethylene naphthalate or polyimide but may be another suitable high-molecular material.

In one preferable structure of the planar element module of the invention, the planar member is processed to have a net-like structure with the multiple element location areas at intersections. In another preferable structure of the planar element module of the invention, the planar member has the multiple element location areas arranged at intervals of not greater than 2 cm. The interval of the multiple element location areas is not restricted to be not greater than 2 cm but may be varied adequately according to the processing accuracy and the other requirements. For example, the interval of the multiple element location areas may be not less than 2 cm or may be, for example, 1 cm, 5 mm, 3 mm, 1 mm, 500 μm, 200 μm, or 100 μm.

In another preferable structure of the planar element module of the invention, each of the multiple elements includes either a sensor, for example, a pressure sensor, a temperature sensor, or a photo sensor, or an actuator as an electrode. Further, each of the multiple elements may include an organic field-effect transistor.

In the planar element module of the invention, the multiple elements may include at least two different types of elements having different functions. The planar element module thus obtained has multiple different functions.

Another application of the invention is a planar element device that includes lamination of an identical type of or different types of plural planar element modules having any of the arrangements described above. In the planar element device of the invention, each of the plural planar element modules has: a planar member having multiple element location areas that are arranged in a substantially identical plane and multiple bridging areas that respectively bridge the multiple element location areas and are bending deformable; multiple elements formed in at least part of the multiple element location areas of the planar member; and a wiring that is made of an electrically conductive material and is formed on at least part of the multiple bridging areas to supply electricity to the multiple elements.

The planar element device of the invention includes the lamination of the plural planar element modules of the invention having any of the arrangements described above. The planar element device of the invention accordingly has the effects of the planar element module of the invention described above and the additional effects of the lamination of the plural planar element modules. As the former effects, the planar element module is tensile in the planar direction and is deformable to a curved surface. Lamination of the identical type of plural planar element modules increases the number of elements formed in unit area. Lamination of the different types of plural planar element modules readily produces the planar element device including elements having multiple different functions.

In the planar element device of the invention, the plural planar element modules may be arranged such that the multiple element location areas of the respective planar element modules are aligned or may be arranged such that the multiple element location areas of the respective planar element modules are not aligned. The former arrangement may be applied to lamination of the different types of plural planar element modules with elements of different functions. This enables the elements of different functions to be located in an identical part. The latter arrangement may be applied to lamination of the identical type of plural planar element modules with elements of an identical function. This easily reduces the interval of the respective elements.

The present invention is also directed to a first manufacturing method of a planar element module. The first manufacturing method includes: an element wiring formation step of forming multiple elements on a thin film of a polymer material and a wiring of an electrically conductive material to supply electricity to the multiple elements; and a processing step of processing the thin film to have element formation areas to receive the multiple elements of the thin film formed therein and wiring areas to receive the wiring of the thin film formed therein and bridge the element formation areas.

The first manufacturing method of the planar element module of the invention is applied to produce the planar element module of the invention that is tensile in the planar direction and is deformable to a curved surface. In the first manufacturing method of the invention, the multiple elements and the wiring are formed on the thin film before the thin film is processed to have the element formation areas and the wiring areas for bridging the element formation areas. This arrangement facilitates formation of the multiple elements and the wiring at any desired positions.

In one aspect of the first manufacturing method of the planar element module of the invention, the element wiring formation step lays out the wiring in a net-like structure and locates the multiple elements at intersections of the net-like structure, and the processing step processes the thin film to the net-like structure.

The present invention is also directed to a second manufacturing method of a planar element module. The second manufacturing method includes: a processing step of processing a thin film of a polymer material to have multiple openings and thereby forming multiple element location areas and multiple bridging areas that respectively bridge the multiple element location areas; and an element wiring formation step of forming multiple elements in at least part of the multiple element location areas and a wiring of an electrically conductive material in at least part of the multiple bridging areas to supply electricity to the multiple elements.

The second manufacturing method of the planar element module of the invention is applied to produce the planar element module of the invention that is tensile in the planar direction and is deformable to a curved surface. In the second manufacturing method of the invention, the thin film is processed to have the element formation areas and the bridging areas, prior to formation of the multiple elements and the wiring on the thin film. This arrangement effectively prevents the potential breakage of wiring and the potential damage of elements in the course of processing the thin film.

In one aspect of the second manufacturing method of the planar element module of the invention, the processing step processes the thin film to a net-like structure.

In the first or second manufacturing method of the planar element module of the invention, the element wiring formation step may form each of the multiple elements that includes either a sensor, for example, a pressure sensor, a temperature sensor, or a photo sensor, or an actuator as an electrode and an organic field-effect transistor.

### BRIEF DESCRIPTION OF THE DRAWINGS

FIG. 1 schematically illustrates the structure of a flat pressure sensor 20 in one embodiment of the invention;

FIG. 2 is a sectional view schematically illustrating the cross section of each pressure sensor element 30;

FIG. 3 shows the stretch of the flat pressure sensor 20;

FIG. 4 is an enlarged view schematically showing an element formation area 26 and bridging areas 28 in a planar member 22 of the flat pressure sensor 20 in a stretched condition;

FIG. 5 is a flowchart showing a manufacturing process of the flat pressure sensor 20;

FIG. 6 is a flowchart showing a formation process of the pressure sensor element 30;

FIG. 7 is a sectional view schematically illustrating the cross section of a temperature sensor element 50; and

FIG. 8 schematically illustrates the structure of a planar element device 70 in one embodiment of the invention.

### BRIEF DESCRIPTION OF THE DRAWINGS

One mode of carrying out the invention is described below as a preferred embodiment with reference to the accompanied drawings.

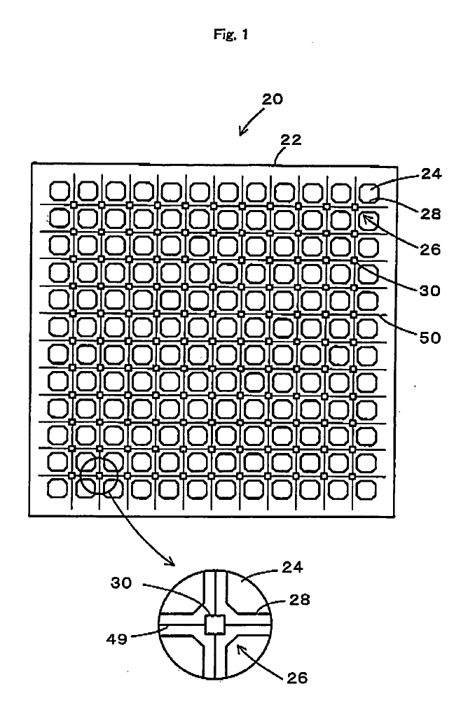

FIG. 1 schematically illustrates the structure of a flat pressure sensor 20 in one embodiment of the invention. As illustrated, the flat pressure sensor 20 of the embodiment includes a planar member 22 that is formed in a net-like structure having plurality of substantially square openings 24, multiple pressure sensor elements 30 respectively placed at intersections of the net-like structure of the planar member 22, and a wiring 49 formed on the net-like structure of the planar member 22 for the multiple pressure sensor elements 30.

The planar member 22 is made of a material having bending deformability and excellent workability (for example, a polymer material). The planar member 22 is a thin film formed to have a thickness of not greater than 1 mm or preferably in a range of 10 μm to 500 μm and has a net-like structure. The net-like structure of the planar member 22 includes plurality of substantially square chamfered (that is, octagonal) openings 24 of 50 μm to 2 cm on each side (preferably 200 μm to 5 mm) arranged in a matrix, plurality of substantially square chamfered (that is, octagonal) element formation areas 26 at the respective intersections of the net-like structure, and plurality of bridging areas 28 spanned between respective pairs of adjacent element formation areas 26. The bridging areas 28 preferably have a width of not less than the thickness of the thin film to ensure the sufficient strength. In this embodiment, the thin film used for the planar member 22 is a polyethylene naphthalate (PEN) film of 125 μm in thickness (Teonex Q65 manufactured by Teijin DuPont Films Japan Limited). The planar member 22 has the plural openings 24 of approximately 2 mm on each side arranged in a matrix with the bridging areas 28 in the width of 3 to 20 times as much as the thickness of the thin film. The planar member 22 is made of the material having bending deformability as mentioned above. The bridging areas 28 are thus in-plane and out-of-plane bending deformable.

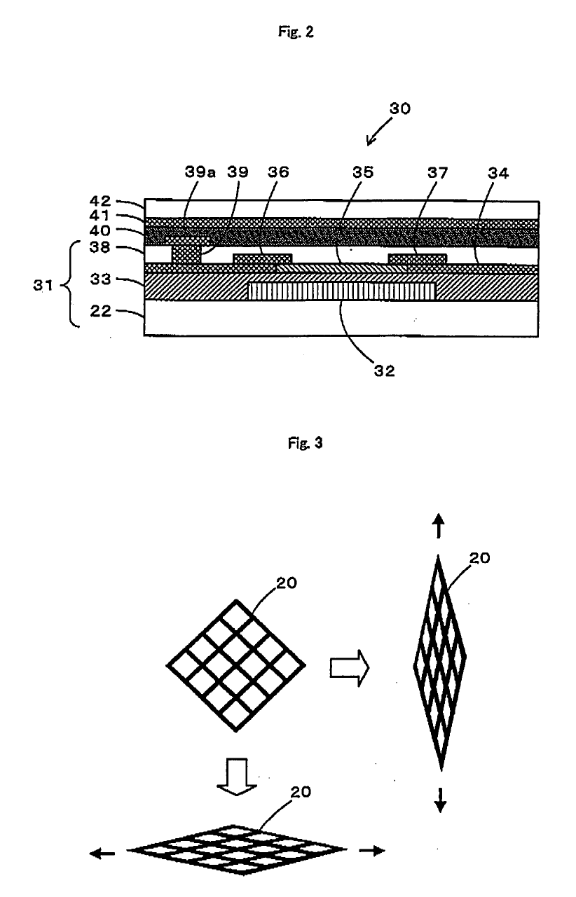

FIG. 2 is a sectional view schematically illustrating the cross section of each pressure sensor element 30. The pressure sensor element 30 mainly includes an organic field-effect transistor 31 formed on the planar member 22 and a pressurized conductive rubber layer 40 as a pressure sensor. The organic field-effect transistor 31 has an organic channel 35 made of, for example, pentacene, three electrodes made of gold (a gate 32, a source 36, and a drain 37), an electrode layer 34 for supplying electricity to the source 36 and the drain 37, a gate insulator film 33 made of, for example, polyimide and interposed between the organic channel 35 and the gate 32, and a parylene protective film 38 made of, for example, polychloro-p-xylylene for protecting the organic channel 35, the source 36, and the drain 37. The source 36 is electrically connected to the pressurized conductive rubber layer 40 through an electrically connected via hole 39 formed in the parylene protective film 38 and an electrode pad 39a mounted on the via hole 39. The pressurized conductive rubber layer 40 may be CSA (PK grade) commercially available from PCR Technical. A polyimide film 42 with a copper foil 41 as a common electrode is stuck to the surface of the pressurized conductive rubber layer 40. The wiring 49 is formed by processing the polyimide film 42 with the copper foil 41 in a net-like structure.

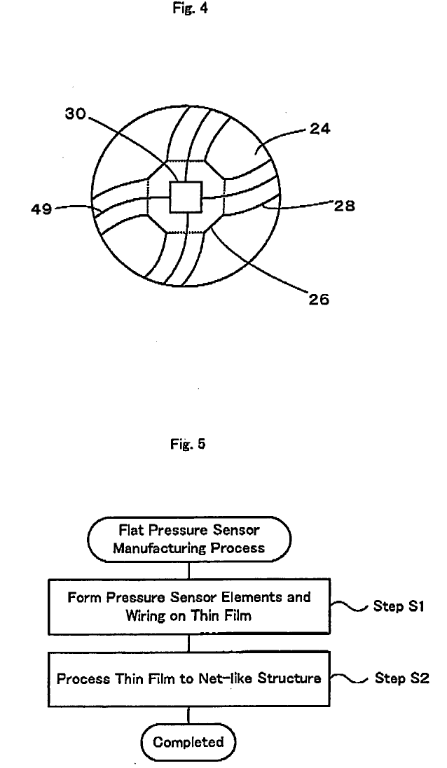

The flat pressure sensor 20 of the embodiment has the net-like structure and is thus stretchable in diagonal directions without arrangement of the bridging areas 28 (upward and downward, leftward and rightward in FIG. 3, in directions of 45 degrees in FIG. 1) under application of a tension. FIG. 4 is an enlarged view schematically showing the element formation area 26 and the bridging area 28a in the planar member 22 of the flat pressure sensor 20 in a stretched condition. As illustrated, in the stretched condition of the flat pressure sensor 20, the bridging elements 28 are slightly bent and deformed, while the element formation areas 26 are hardly deformed. In the structure of this embodiment, each element formation area 26 is chamfered by chamfering the surrounding openings 24. This structure enhances the shape maintaining effect of the element formation areas 26 and keeps the element formation areas 26 non-deformed even in the stretched condition of the flat pressure sensor 20. The bridging areas 28 are slightly in-plane bending deformable, as well as out-of-plane bending deformable as mentioned previously. The flat pressure sensor 20 of the embodiment is thus not only stretchable in the diagonal directions without arrangement of the bridging areas 28 but readily bent to a curved surface with the stretch in the diagonal directions without arrangement of the bridging areas 28. In any state, the element formation areas 26 are not deformed. The flat pressure sensor 20 of the embodiment is stretchable by at least 200% in the diagonal directions without arrangement of the bridging areas 28 and is deformable to any adjustable surface, for example, by mounting on a spherical surface. The durability against the repeated stretch depends upon the material and the thickness of the planar member 22 and the degree of stretch. The repeated 200% stretches of more than 7000 times did not cause any breakage or significant damage on the flat pressure sensor 20 of the embodiment. Namely the flat pressure sensor 20 of the embodiment is sufficiently durable.

The following describes the manufacture of the flat pressure sensor 20 of the embodiment. FIG. 5 is a flowchart showing a manufacturing process of the flat pressure sensor 20. The flat pressure sensor manufacturing process of the embodiment forms the pressure sensor elements 30 and the wiring 49 on the thin film (step S1) and processes the thin film to the net-like structure to complete the flat pressure sensor 20 (step S2).

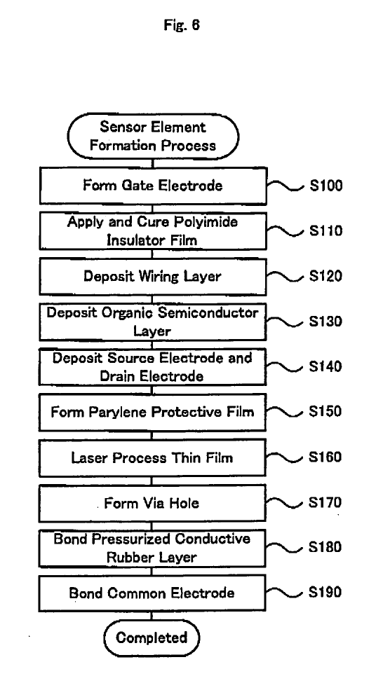

Each sensor element, for example, the pressure sensor element 30, may be formed according to a procedure in the flowchart of FIG. 6. Formation of the pressure sensor element 30 of the embodiment is described briefly with reference to a concrete example. The sensor element formation process first applies a metal mask for patterning to a polyethylene terephthalate film of 125 μm in thickness, which is processed to have a negligible range of thermal contraction or deformation in the course of sensor element deformation. The sensor element formation method accordingly forms the gate 32 of chromium (Cr) having a film thickness of 5 nm and of gold (Au) having a film thickness of 150 nm on the patterned polyethylene terephthalate film by vacuum deposition (degree of vacuum: 1×10⁻⁴ to 5×10⁻⁴ Pa, deposition rate: 5 to 7 nm/min) (step S100). The sensor element formation process subsequently forms the gate insulator film 33 on the gate 32 by spin coating a polyimide precursor (KEMITITE CT4112 manufactured by Kyocera Chemical Corporation) at 6000 rpm for 120 seconds (step Silo). The chromium (Cr) layer of the gate 32 is used as an adhesive layer. The sensor element formation process then applies a metal mask for patterning and forms the electrode layer 34 of gold (Au) having a film thickness of 60 nm and the wiring 49 by vacuum deposition (step S120). The sensor element formation process subsequently forms a film of pentacene, which has the purity of not lower than 98% and is a commercially available Aldrich brand or Fluka brand from Sigma Aldrich Corporation, by vacuum deposition (degree of vacuum: 2×10⁻⁵ to 5×10⁻⁵ Pa), to give the organic channel 35 having a film thickness of 50 nm (step S130). The sensor element formation process applies a metal mask for patterning and forms the source 36 and the drain 37 of gold (Au) having a film thickness of 60 nm by vacuum deposition (step S140). In order to prevent deterioration of the organic channel 35, the parylene (polychloro-p-xylylene) protective film 38 of 2 μm in thickness is formed on the sensor matrix by CVD (chemical vapor deposition) (step S150). Laser processing of the parylene protective film 38 forms the via hole 39 to attain electrical connection between the source 36 and the sensor (pressurized conductive rubber layer 40) (step S160). The sensor element formation process applies a metal mask for patterning and forms the electrode pad 39a of chromium (Cr) having a film thickness of 5 nm and of gold (Au) having a film thickness of 150 nm with the via hole 39 by vacuum deposition (degree of vacuum: 1×10⁻⁴ to 5×10⁻⁴ Pa, deposition rate: 5 to 7 nm/min) (step S170). This complete the organic field-effect transistor 31. The commercially available pressurized conductive rubber layer 40 (CSA, PK grade manufactured by PCR Technical) is bonded to the surface of the organic field-effect transistor 31 (step S180). The polyimide film 42 with the copper foil 41 is joined with the pressurized conductive rubber layer 40, such that the copper foil 41 is placed between the polyimide film 42 and the pressurized conductive rubber layer 40 (step S190). This completes the pressure sensor element 30.

The thin film with the pressure sensor elements 30 formed thereon is pressed or processed to the net-like structure (step S2 in the flowchart of FIG. 5) with, for example, a cutting plotter, an NC drill, an NC punching machine. The thin film is securely fastened to a base by an adhesive sheet to prevent deflection or uplift.

The net-like structure described above enables the flat pressure sensor 20 of the embodiment to be stretched in the diagonal directions without arrangement of the bridging areas 28, while not deforming the element formation areas 26. The bridging areas 28 are in-plane bending deformable and out-of-plane bending deformable to a curved surface. The flat pressure sensor 20 of the embodiment is thus readily mountable on a curved surface, for example, a spherical surface. In the flat pressure sensor 20 of the embodiment, the bridging areas 28 have the width of not less than the thickness of the thin film. Each of the openings 24 may be not less than several hundred μm on each side, and each of the pressure sensor elements 30 may be not greater than several hundred μm on each side. This enables the layout of a large number of pressure sensor elements 30 per unit area. The use of the flat pressure sensor 20 of the embodiment attached to any adjustable surface enables the pressure applied to the adjustable surface to be accurately detected in a detailed distribution.

The flat pressure sensor manufacturing process of the embodiment allows highly accurate production of the flat pressure sensor 20 that is tensile and is attachable to any adjustable surface. After formation of the pressure sensor elements 30 and the wiring 49 on the thin film, the thin film is processed to the net-like structure. This arrangement facilitates formation of the pressure sensor elements 30 and the wiring 49 at desired positions.

The element formed in each element formation area 26 of the planar member 22 is not restricted to the pressure sensor element 30 described in the above embodiment but may be a temperature sensor element for measuring the temperature or a photo sensor element for detecting light, such as a CCD. The structure of a temperature sensor element 50 is described with reference to FIG. 7. As illustrated, the temperature sensor element 50 has an organic field-effect transistor 31 and a temperature sensor 51 bonded to each other by a conductive paste 60. The temperature sensor 51 utilizes the temperature dependency of a resistance in a forward bias of an organic PN junction device. The temperature sensor 51 includes a P-type organic semiconductor 53 with an anode 52 and an N-type organic semiconductor 54 with a cathode 55. The anode 52, the P-type organic semiconductor 53, the N-type organic semiconductor 54, and the cathode 55 are formed in this order on a polyethylene naphthalate film, and are covered with a parylene protective film 55 for protection. Like the parylene protective film 38 of the organic field-effect transistor 31, the parylene protective film 56 has a via hole 57 and an electrode pad 58 mounted on the via hole 57. The conductive paste 60 connects the electrode pad 58 of the temperature sensor 51 with the electrode pad 39a of the organic field-effect transistor 31. The production of the temperature sensor 51 is not characteristic of the invention and is not described in detail. In the structure of the embodiment, the pressure sensor element 30 is formed in each element formation area 26 of the planar member 22. The element formed in each element formation area 26 of the planar member 22 may otherwise be an actuator, for example, an electrode for application of a voltage or an electrode for radiation of electric wave.

In the structure of the embodiment, the pressure sensor elements 30 are formed in all the element formation areas 26 of the planar member 22. In one possible modification, the pressure sensor elements 30 may be formed in only some part of the element formation areas 26 of the planar member 22. In another possible modification, the pressure sensor elements 30 may be formed in one part of the element formation areas 26 of the planar member 22, while the different sensors (for example, temperature sensors or photo sensors) other than the pressure sensor elements 30 or the actuators may be formed in the residual part of the element formation areas 26 of the planar member 22.

In the flat pressure sensor 20 of the embodiment, formation of the plurality of substantially square openings 24 on the thin film gives the planar member 22 having the multiple element formation areas 26 respectively bridged by the multiple bridging areas 28. This structure is, however, not restrictive but the flat pressure sensor 20 is required to be tensile in at least one direction by vending deformation of the bridging areas 28. The openings 24 are thus not restricted to have the substantially square shape but may have any suitable shape other than the substantially square shape. Formation of plurality of openings in any suitable shape gives a planar member having multiple element formation areas respectively bridged by multiple bridging areas. For example, the openings may be formed on the thin film to have a honey comb structure. Such modification enhances the degree of freedom in the tensile direction of the flat sensor.

The polyethylene naphthalate thin film is used for the flat pressure sensor 20 of the embodiment. The polyethylene naphthalate thin film is, however, not restrictive, but a thin film may be made of any of diverse polymer materials, for example, polyimide.

The flat pressure sensor manufacturing process of the embodiment processes the thin film to the net-like structure after formation of the pressure sensor elements 30 and the wiring 49 on the thin film. One possible modification may form the pressure sensor elements 30 and the wiring 49 on the thin film after processing the thin film to the net-like structure. This modified procedure effectively prevents the potential breakage of wiring and the potential damage of an element formed in each element formation area 26 in the course of processing the thin film to the net-like structure. This modified procedure also provides the flat pressure sensor 20 that is tensile and is attachable to any adjustable surface. In this modification, the pressure sensor element formation process of FIG. 6 is applicable to formation of each pressure sensor element.

The flat pressure sensor manufacturing process of the embodiment processes the thin film to the net-like structure after formation of the organic field-effect transistors 31 on the thin film and coating of the organic field-effect transistors 31 with the pressurized conductive rubber layer 40 and the polyimide film 42 with the copper foil 41. One possible modification may process the thin film to the net-like structure immediately after formation of the organic field-effect transistors 31 on the thin film. In this case, the pressurized conductive rubber layer 40 and the polyimide film 42 with the copper foil 41 are processed to the net-like structure and are then bonded to the organic field-effect transistors 31.

The flat pressure sensor manufacturing process of the embodiment processes the thin film to the net-like structure after formation of the pressure sensor elements 30 and the wiring 49 on the thin film. One possible modification may combine warp elements and weft elements to provide a net-like member and form element formation areas 26 at the respective intersections of the net-like member. Subsequent formation of the pressure sensor elements 30 and the wiring 49 on the element formation areas 26, the warm elements, and the weft elements completes the flat pressure sensor 20.

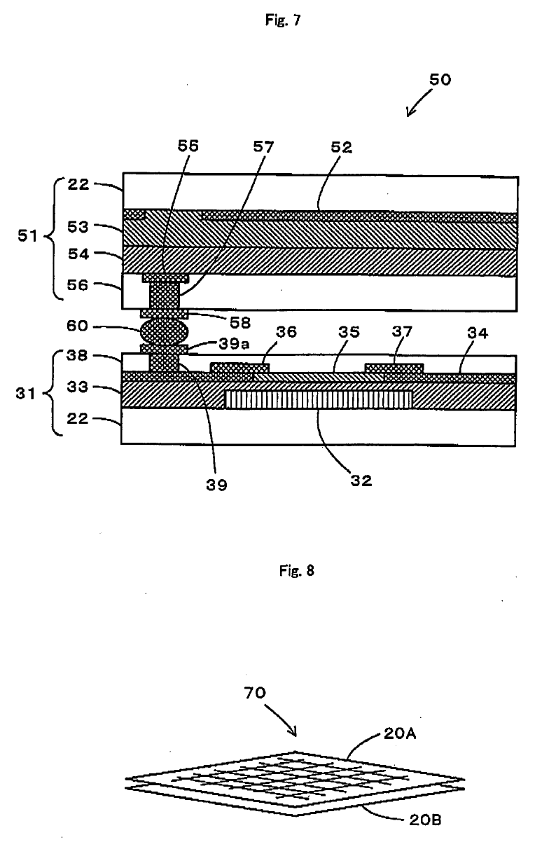

A planar element device 70 in one embodiment of the invention is described below. FIG. 8 shows the structure of the planar element device 70 of the embodiment. As illustrated, the planar element device 70 of the embodiment includes a flat pressure sensor 20A having pressure sensor elements 30 formed in all element formation areas 26 of a planar member 22 and a flat temperature sensor 20B having temperature sensor elements 50 formed in all element formation areas 26 of a planar member 22. The flat pressure sensor 20A and the flat temperature sensor 20B are processed to have an identical net-like structure and are laid one upon the other, such that the element formation areas 26 of the flat pressure sensor 20A are aligned to the element formation areas 26 of the flat temperature sensor 20B (not specifically illustrated).

The planar element device 70 of the embodiment is the lamination of the flat pressure sensor 20A, which is identical with the flat pressure sensor 20 of the embodiment, and the flat temperature sensor 20B, which is described above as the modified example. The planar element device 70 of the embodiment is thus tensile in diagonal directions without arrangement of the bridging areas 28 of the flat pressure sensor 20A and the flat temperature sensor 20B and is deformable to a curved surface. The flat pressure sensor 20A and the flat temperature sensor 20B are laid one upon the other, such that the element formation areas 26 of the flat pressure sensor 20A are aligned to the element formation areas 26 of the flat temperature sensor 20B. This layout enables simultaneous detection of the pressure and the temperature at identical positions of a curved surface to which the planar element device 70 is attached.

In the planar element device 70 of the embodiment, the flat pressure sensor 20A and the flat temperature sensor 20B are laid one upon the other such that the element formation areas 26 of the flat pressure sensor 20A are aligned to the element formation areas 26 of the flat temperature sensor 20B. In one modified structure, the flat pressure sensor 20A and the flat temperature sensor 20B may be laid one upon the other such that the element formation areas 26 of the flat pressure sensor 20A are not aligned to the element formation areas 26 of the flat temperature sensor 20B. This modified layout enables the accuracy of the inside-located sensors to be equivalent to the accuracy of the outside-located sensors.

The planar element device 70 of the embodiment is the lamination of the flat pressure sensor 20A and the flat temperature sensor 20B. One modified structure of the planar element device may be lamination of two flat pressure sensors 20A. In this case, the two flat pressure sensors 20A may be laid one upon the other such that the element formation areas 26 of one flat pressure sensor 20A are not aligned with the element formation areas 26 of the other pressure sensor 20A. This increases the number of pressure sensor elements 30 formed in unit area. In another possible modification, the planar element device may be lamination of three or more flat pressure sensors 20A, which are laid one upon another such that the element formation areas 26 of the respective flat pressure sensors 20A are not aligned. This modification further increases the number of pressure sensor elements 30 formed in unit area. As mentioned above, the flat sensors to be laid one upon another are not restricted to the flat pressure sensors 20A. This modification thus increases the number of temperature sensor elements 50, the number of photo sensor elements, or the number of actuator elements per unit area.

The planar element device 70 of the embodiment is the lamination of the flat pressure sensor 20A and the flat temperature sensor 20B. A flat photo sensor with multiple photo sensor elements formed in respective element formation areas 26 may further be laid on the lamination of the flat pressure sensor 20A and the flat temperature sensor 20B. Namely the planar element device may be obtained as lamination of three or more flat sensors or flat actuators.

The embodiment and its modified examples discussed above are to be considered in all aspects as illustrative and not restrictive. There may be many modifications, changes, and alterations without departing from the scope or spirit of the main characteristics of the present invention.

### INDUSTRIAL APPLICABILITY

The technique of the invention is preferably applicable to the manufacturing industries of flat sensors for measurement of physical quantities and flat actuators and other relevant industries.

1. A planar element module, comprising:
a planar member having multiple element location areas that are arranged in a substantially identical plane and multiple bridging areas that respectively bridge the multiple element location areas and are bending deformable;
multiple elements formed in at least part of the multiple element location areas of the planar member; and
a wiring that is made of an electrically conductive material and is formed on at least part of the multiple bridging areas to supply electricity to the multiple elements.

2. The planar element module in accordance with claim 1, wherein the planar member has the multiple bridging areas that are bent and deformed to be stretched in a predetermined direction by application of a tension in the predetermined direction.

3. The planar element module in accordance with claim 2, wherein the planar member has the multiple bridging areas that are arranged in a different direction from the predetermined direction.

4. The planar element module in accordance with claim 1, wherein the planar member having the multiple element location areas and the multiple bridging areas is provided by formation of plural openings on a thin film of a polymer material.

5. The planar element module in accordance with claim 4, wherein the thin film is either a polyethylene naphthalate film having a thickness of not greater than 1 mm or a polyimide film having a thickness of not greater than 1 mm.

6. The planar element module in accordance with claim 1, wherein the planar member is processed to have a net-like structure with the multiple element location areas at intersections.

7. The planar element module in accordance with claim 1, wherein the planar member has the multiple element location areas arranged at intervals of not greater than 2 cm.

8. The planar element module in accordance with claim 1, wherein each of the multiple elements includes either a sensor, for example, a pressure sensor, a temperature sensor, or a photo sensor, or an actuator as an electrode.

9. The planar element module in accordance with claim 1, wherein each of the multiple elements includes an organic field-effect transistor.

10. The planar element module in accordance with claim 1, wherein the multiple elements include at least two different types of elements having different functions.

11. A planar element device including lamination of an identical type of or different types of plural planar element modules, the planar element modules respectively comprising:
planar member having multiple element location areas that are arranged in a substantially identical plane and multiple bridging areas that respectively bridge the multiple element location areas and are bending deformable;
multiple elements formed in at least part of the multiple element location areas of the planar member; and
a wiring that is made of an electrically conductive material and is formed on at least part of the multiple bridging areas to supply electricity to the multiple elements.

12. The planar element device in accordance with claim 11, wherein the plural planar element modules are arranged such that the multiple element location areas of the respective planar element modules are aligned.

13. The planar element device in accordance with claim 11, wherein the plural planar element modules are arranged such that the multiple element location areas of the respective planar element modules are not aligned.

14. A manufacturing method of a planar element module, the manufacturing method comprising:
an element wiring formation step of forming multiple elements on a thin film of a polymer material and a wiring of an electrically conductive material to supply electricity to the multiple elements; and
a processing step of processing the thin film to have element formation areas to receive the multiple elements of the thin film formed therein and wiring areas to receive the wiring of the thin film formed therein and bridge the element formation areas.

15. The manufacturing method in accordance with claim 14, wherein the element wiring formation step lays out the wiring in a net-like structure and locates the multiple elements at intersections of the net-like structure, and
the processing step processes the thin film to the net-like structure.

16. A manufacturing method of a planar element module,
a processing step of processing a thin film of a polymer material to have multiple openings and thereby forming multiple element location areas and multiple bridging areas that respectively bridge the multiple element location areas; and
an element wiring formation step of forming multiple elements in at least part of the multiple element location areas and a wiring of an electrically conductive material in at least part of the multiple bridging areas to supply electricity to the multiple elements.

17. The manufacturing method in accordance with claim 16, wherein the processing step processes the thin film to a net-like structure.

18. The manufacturing method in accordance with claim 14, wherein the element wiring formation step forms each of the multiple elements that includes either a sensor, for example, a pressure sensor, a temperature sensor, or a photo sensor, or an actuator as an electrode and an organic field-effect transistor.

19. The manufacturing method in accordance with claim 16, wherein the element wiring formation step forms each of the multiple elements that includes either a sensor, for example, a pressure sensor, a temperature sensor, or a photo sensor, or an actuator as an electrode and an organic field-effect transistor.
